(19) United States
(12) Patent Application Publication
(10) Pub. No.: US 2023/0315941 A1
(43) Pub. Date: Oct. 5, 2023

(54) SIMULATION DEVICE

(71) Applicant: HONDA MOTOR CO., LTD., TOKYO (JP)

(72) Inventors: Kei HIROHATA, TOKYO (JP); Hiroaki MARUYAMA, TOKYO (JP); Jun OHASHI, TOKYO (JP); Naohiro AKUZAWA, TOKYO (JP); Daisuke IDE, TOKYO (JP); Yohei UMEMOTO, TOKYO (JP); Adil GUPTA, TOKYO (JP); Yuichi NAKAMURA, TOKYO (JP)

(21) Appl. No.: 18/126,652

(22) Filed: Mar. 27, 2023

(30) Foreign Application Priority Data
Mar. 30, 2022 (JP) 2022-056731

(51) Int. Cl. G06F 30/20; G07C 5/04

(52) U.S. Cl. CPC G06F 30/20; G07C 5/04

(57) ABSTRACT

A simulation device is equipped with a travel information acquisition unit that acquires travel information from an internal combustion engine vehicle, an electric vehicle information storage unit that stores electric vehicle information about traveling performance of an electric vehicle, a map information storage unit that stores map information, an electric energy calculating unit that calculates electric energy required for a round trip between a storage location of the internal combustion engine vehicle and a destination, an area estimation unit that estimates a charging required area where the electric vehicle needs to be charged during the round trip, and an output unit that causes an information terminal of a user to output the charging required area.

### CROSS-REFERENCE TO RELATED APPLICATIONS

This application is based upon and claims the benefit of priority from Japanese Patent Application No. 2022-056731 filed on Mar. 30, 2022, the contents of which are incorporated herein by reference.

### BACKGROUND OF THE INVENTION

### Field of the Invention

The present invention relates to a simulation device.

### Description of the Related Art

JP 2014-235709 A discloses an electric energy consumption estimating apparatus for estimating the electric energy in a battery consumed by an electric vehicle.

### SUMMARY OF THE INVENTION

According to the disclosure of JP 2014-235709 A, it is possible to estimate the electric energy required for daily use of an electric vehicle. However, there is a problem that a user himself/herself cannot estimate an area where an electric vehicle needs to be charged on a daily basis. Therefore, there are some users who hesitate to buy an electric vehicle to replace his/her internal combustion engine vehicle.

An object of the present invention is to solve the above-described problems.

According to an aspect of the present invention, a simulation device includes a travel information acquisition unit configured to acquire travel information from an internal combustion engine vehicle equipped with an internal combustion engine, the travel information including a travel history of the internal combustion engine vehicle, an electric vehicle information storage unit configured to store electric vehicle information about traveling performance of the electric vehicle, a map information storage unit configured to store map information including road information, an electric energy calculating unit configured to calculate electric energy required in a case where the electric vehicle is used for a round trip between a storage location of the internal combustion engine vehicle and a destination based on the travel information, based on the electric vehicle information and the travel information acquired during a predetermined period, an area estimation unit configured to estimate a charging required area in which the electric vehicle needs to be charged during the round trip, based on the calculated electric energy, the electric vehicle information, and the map information, and an output unit configured to cause an information terminal of a user of the internal combustion engine vehicle to output the charging required area.

According to the present invention, the user can recall the image of using the electric vehicle.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a diagram exemplifying a network connection configuration of a simulation device according to an embodiment;

FIG. 2 is a block diagram illustrating the configuration of the simulation device;

FIG. 3 is a diagram exemplifying travel information;

FIG. 4 is a diagram exemplifying electric vehicle information;

FIG. 5 is a diagram exemplifying a data structure of map information;

FIG. 6 is a diagram exemplifying on a road map a state in which it is assumed that a user travels between a home parking lot and his/her work place as a destination by an electric vehicle;

FIG. 7 is a diagram for explaining an area requiring charging;

FIG. 8 is a diagram exemplifying a screen displayed for a user to input charging equipment information into an information terminal;

FIG. 9 is a diagram illustrating a state in which a charging required area is output to the user's information terminal;

FIG. 10 is a flowchart illustrating a processing procedure relating to acquisition of travel information by the simulation device; and

FIG. 11 is a flowchart illustrating a processing procedure relating to estimation of the charging required area by the simulation device.

### DETAILED DESCRIPTION OF THE INVENTION

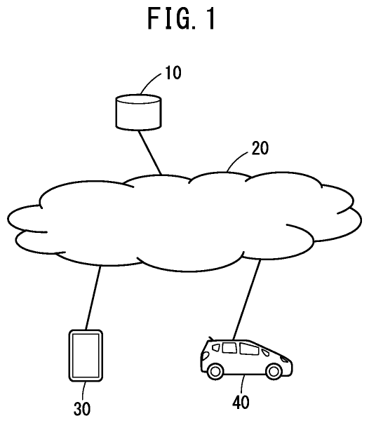

FIG. 1 is a diagram exemplifying a network connection configuration of a simulation device 10 according to an embodiment. An information terminal 30 of a user and an internal combustion engine vehicle 40 of the user are connected to the simulation device 10 via a communication network 20.

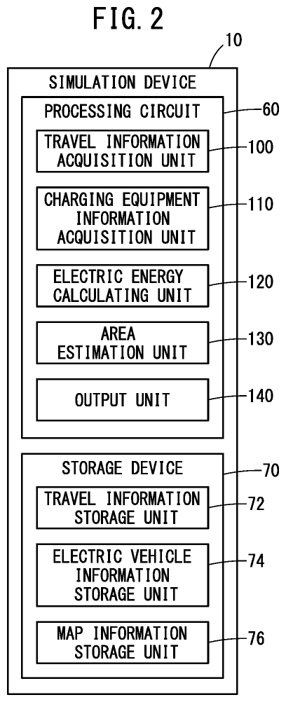

FIG. 2 is a block diagram illustrating the configuration of the simulation device 10. The simulation device 10 includes a processing circuit 60 and a storage device 70. The processing circuit 60 includes a processor such as a CPU or a GPU. The storage device 70 includes a volatile memory such as a RAM and a non-volatile memory such as a ROM or a flash memory. The volatile memory is used as a working memory of the processor. The non-volatile memory stores programs executed by the processor and other necessary data. The storage device 70 includes a travel information storage unit 72, an electric vehicle information storage unit 74, and a map information storage unit 76. The travel information, the electric vehicle information and the map information will be described later.

The processing circuit 60 includes a travel information acquisition unit 100, a charging equipment information acquisition unit 110, an electric energy calculating unit 120, an area estimation unit 130, and an output unit 140. When the processing circuit 60 executes the program stored in the storage device 70, the travel information acquisition unit 100, the charging equipment information acquisition unit 110, the electric energy calculating unit 120, the area estimation unit 130, and the output unit 140 are implemented. At least a part of the travel information acquisition unit 100, the charging equipment information acquisition unit 110, the electric energy calculating unit 120, the area estimation unit 130, and the output unit 140 may be implemented by an integrated circuit such as an ASIC or an FPGA or an electronic circuit including a discrete device.

The travel information acquisition unit 100 acquires travel information including travel history of the internal combustion engine vehicle 40 from the internal combustion engine vehicle 40. The travel information acquisition unit 100 stores the acquired travel information in the travel information storage unit 72.

In the present embodiment, the user uses a parking lot at home (also referred to as a home parking lot) as a storage location for the internal combustion engine vehicle 40. In this case, it is assumed that when the user switches from the use of the internal combustion engine vehicle 40 to the use of an electric vehicle, the electric vehicle is stored in the parking lot of the user's home on a daily basis. A storage location of the internal combustion engine vehicle 40 may be a parking lot other than the home parking lot of the user. For example, the storage location may be a parking lot in the vicinity of the home.

The charging equipment information acquisition unit 110 acquires charging equipment information about whether or not charging equipment is installed in the home parking lot. If the charging equipment is installed in the home parking lot, the electric vehicle is charged while being stored in the parking lot and becomes a fully charged state. In a fully charged state of the electric vehicle, the SOC of the battery of the electric vehicle is 100%. The user inputs charging equipment information on a charging equipment information input screen displayed on the information terminal 30 of the user. The charging equipment information acquisition unit 110 acquires the input charging equipment information from the information terminal 30.

Based on travel information acquired during a predetermined period (for example, one day, one week, or the like), the electric energy calculating unit 120 determines at least one travel point recorded in the travel information as a destination. The electric energy calculating unit 120 calculates the travel distance of the internal combustion engine vehicle 40 in a round trip between the home parking lot and the destination, on the basis of travel information acquired during the predetermined period. Based on the calculated travel distance and the electric power consumption of the electric vehicle, the electric energy calculating unit 120 calculates the amount of electric energy required when the user uses the electric vehicle for a round trip between the home parking lot and the destination.

If the charging equipment is installed in the home parking lot of the user, the area estimation unit 130 determines that the SOC of the battery of the electric vehicle at the time when the user leaves home is 100%. In this case, the electric vehicle is in a fully charged state. If the charging equipment is not installed in the home parking lot of the user, the area estimation unit 130 determines the SOC of the battery of the electric vehicle at the time when the user leaves home to be a predetermined value other than 100% (for example, 80%).

The area estimation unit 130 estimates a charging required area based on the determined SOC, the amount of electric energy calculated by the electric energy calculating unit 120, the electric vehicle information stored in the electric vehicle information storage unit 74, and the map information stored in the map information storage unit 76. The charging required area is an area in which the electric vehicle needs to be charged during the round trip when the user uses the electric vehicle for the round trip between the home parking lot and the destination.

The area estimation unit 130 further determines the position of an available charging facility among the charging facilities installed in the charging required area, based on the map information and the travel information acquired during the predetermined period. For example, a charging facility that is open during a time period when an electric vehicle travels in the charging required area is set as an available charging facility, and the position of the charging facility is determined.

The output unit 140 causes the information terminal 30 of the user to output the above-mentioned charging equipment information input screen. The output unit 140 causes the information terminal 30 of the user to output the charging required area estimated by the area estimation unit 130 together with the road map and the charging facility information.

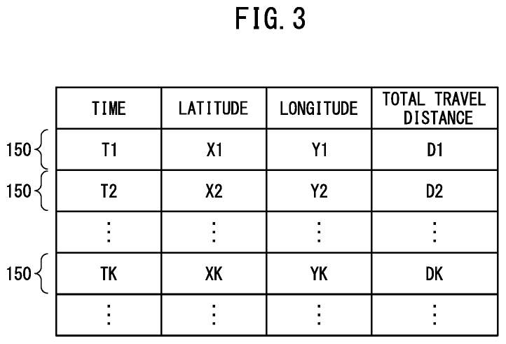

FIG. 3 is a diagram exemplifying travel information 150. The travel information 150 includes the travel history of the internal combustion engine vehicle 40. The travel history is acquired from various sensors mounted on the internal combustion engine vehicle 40. As shown in FIG. 3, the travel information 150 includes a travel history relating to at least time, a location of the travel point, and a total travel distance. The location of the travel is expressed by latitude and longitude. The travel information 150 may further include a travel history regarding speed, acceleration, engine torque, remaining fuel amount, and the like. The travel information 150 is repeatedly transmitted to the simulation device 10.

When the travel information acquisition unit 100 of the simulation device 10 acquires the travel information 150 from the internal combustion engine vehicle 40, the travel information acquisition unit 100 stores the travel information 150 in the travel information storage unit 72 as described above. The travel information 150 is associated with a vehicle ID of the internal combustion engine vehicle 40, a user ID of the internal combustion engine vehicle 40, and a terminal ID of the information terminal 30 operated by the user.

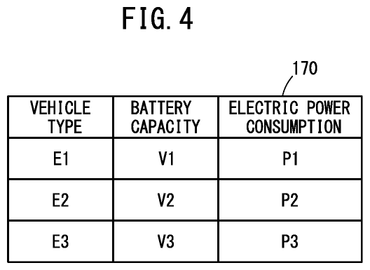

FIG. 4 is a diagram exemplifying electric vehicle information 170. The electric vehicle information 170 is stored in advance in the electric vehicle information storage unit 74 for each type of electric vehicle. The electric vehicle information 170 includes a battery capacity and an electric power consumption relating to the traveling performance of the electric vehicle. In the example shown in FIG. 4, battery capacities V1, V2, and V3 are stored corresponding to electric vehicles of vehicle types E1, E2, and E3, respectively. Electric power consumptions P1, P2, and P3 are stored corresponding to the electric vehicles of the vehicle types E1, E2, and E3, respectively.

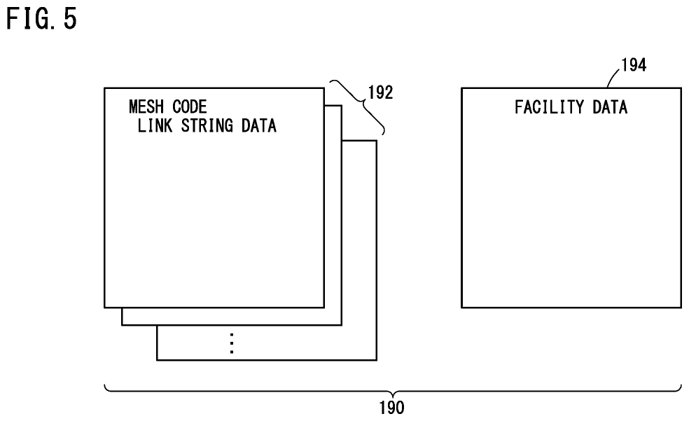

FIG. 5 is a diagram exemplifying a data structure of map information 190. The data of the map information 190 includes mesh data 192 corresponding to a plurality of meshes, respectively, and facility data 194. For each of the meshes, the mesh data 192 each include at least a mesh code and link string data of road links. The facility data 194 include location information and detailed information of facilities such as public facilities, commercial facilities, and tourist facilities. That is, the map information 190 includes road information and facility information.

The facility information includes charging facility information. The charging facility information includes position information of the charging facility expressed by latitude and longitude, and detailed information of the charging facility. The detailed information of the charging facility includes, for example, a facility name, address, business hours, fixed holidays, the number of parking lots, and the number of pieces of fast charging equipment.

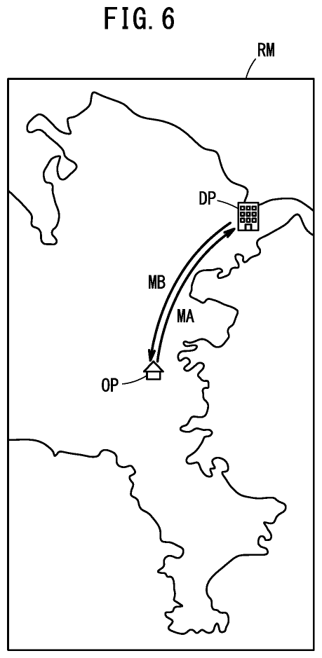

FIG. 6 is a diagram exemplifying on a road map RM a state in which it is assumed that the user travels between a home parking lot of the user's home OP and his/her work place DP as a destination by an electric vehicle. In order to make FIG. 6 easier to see, the road information is omitted on the road map RM of FIG. 6. A route, based on the travel information 150 including the travel history of the internal combustion engine vehicle 40, is used for a round trip between the home OP and the work place DP using the electric vehicle. However, FIG. 6 does not show a specific route. FIG. 6 schematically shows an outward route MA from the home OP to the work place DP and a homeward route MB from the work place DP to the home OP.

As described above, the SOC of the battery of the electric vehicle at the time when the user departs from the home OP is 100% or a predetermined value other than 100%. The area estimation unit 130 calculates an electric energy remaining amount of the battery, based on its SOC and the battery capacity included in the electric vehicle information 170. The area estimation unit 130 compares the calculated electric energy remaining amount of the battery with the electric energy required for the round trip calculated by the electric energy calculating unit 120. When the electric energy remaining amount of the battery is smaller than the electric energy required for the round trip, it is necessary to charge the electric vehicle during the round trip between the home OP and the work place DP. In this case, the area estimation unit 130 estimates a point at which the battery electric power will be exhausted.

The point at which the battery power will be exhausted is estimated by distinguishing whether it is included in the outward route MA or the homeward route MB. The area estimation unit 130 estimates an area including a point where the electric power of the battery is estimated to be exhausted and another point where the electric vehicle will travel before the point, as the above-described charging required area. The charging required area need not necessarily include the point where the electric power of the battery is estimated to be exhausted. The charging required area includes, for example, a point where the SOC of the battery falls below a predetermined value (for example, 20%) during the travel of the electric vehicle before the electric power of the battery is exhausted.

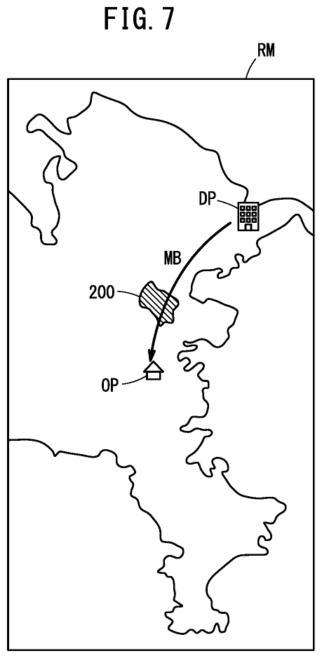

FIG. 7 is a diagram for explaining a charging required area 200. In order to make FIG. 7 easier to see, the road information is omitted on the road map RM of FIG. 7. FIG. 7 shows an example in which a point where the electric power of the battery is exhausted is included in the homeward route MB. The same is true even when the point at which the electric power of the battery is exhausted is included in the outward route MA. As described above, the charging required area 200 includes another point through which the electric vehicle passes before the point where the electric power of the battery is estimated to be exhausted.

Therefore, a section within a predetermined range on the route along which the electric vehicle travels is included in the charging required area 200. If there are a plurality of routes on which the electric vehicle can travel as the homeward route MB, a plurality of sections corresponding to the respective routes are included in the charging required area 200. A contour line of the charging required area 200 is determined based on the road link data included in the map information 190.

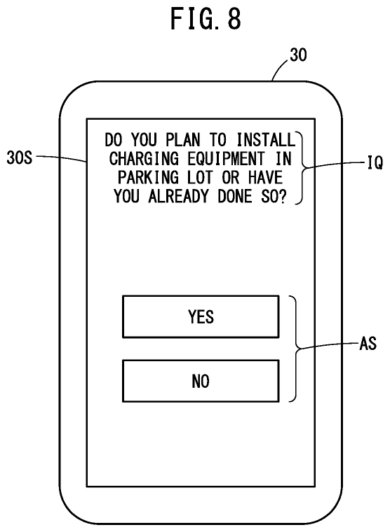

Next, a screen displayed on the user's information terminal 30 will be described. FIG. 8 is a diagram exemplifying a screen displayed for a user to input charging equipment information into the information terminal 30. The output unit 140 causes a display unit 30S of the information terminal 30 of the user to output a charging equipment information input screen. On the charging equipment information input screen, an inquiry IQ regarding whether or not charging equipment is installed in the parking lot of the user's home OP, and an image AS of a button for answering the inquiry IQ are displayed. When the user touches any one of the buttons of the displayed image AS, the charging equipment information is input. Thus, the charging equipment information acquisition unit 110 can acquire the charging equipment information of the user.

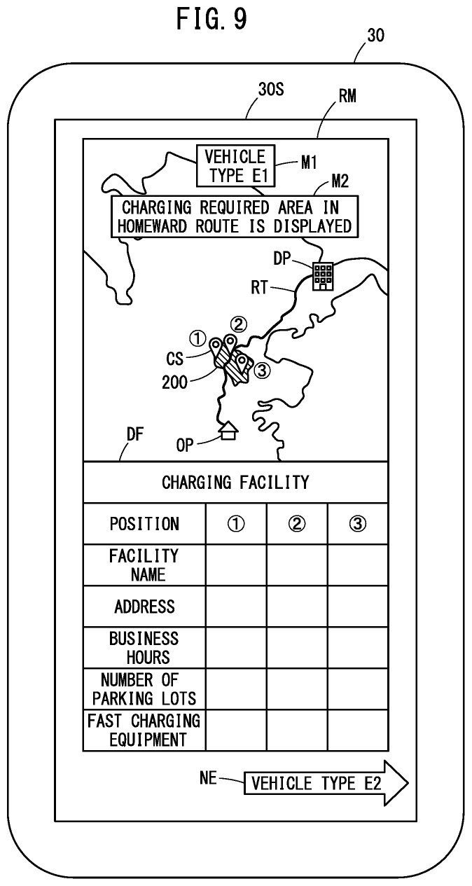

FIG. 9 is a diagram illustrating a state in which the charging required area 200 is output to the information terminal 30 of the user. The output unit 140 causes the display unit 30S of the information terminal 30 to output a screen indicating the charging required area 200 estimated by the area estimation unit 130. The charging required area 200 is displayed on the road map RM. In order to make FIG. 9 easier to see, the road information is omitted from the road map RM. Further, icons CS indicating the positions of available charging facilities are superimposed and displayed on the charging required area 200. The road map RM, the charging required area 200, and the icons CS indicating the position of charging facilities are drawn based on the road information and the facility information of the map information 190.

A message box M1 indicates that the charging required area 200 is displayed if the electric vehicle of the vehicle type E1 is used for the round trip between the home OP and the work place DP. When the user touches an icon NE corresponding to the vehicle type E2, the screen is switched to a screen showing the charging required area 200 if the electric vehicle of the vehicle type E2 is used for the round trip between the home OP and the work place DP.

In FIG. 9, as described in a message box M2, the charging required area 200 in the homeward route MB between the home OP and the work place DP is displayed. The homeward route MB is displayed as a route RT from the work place DP to the home OP. The electric vehicle traveling on the route RT needs to be charged at a charging facility located in the charging required area 200. Among the plurality of charging facilities installed in the charging required area 200, there is a possibility that an unavailable charging facility is included. The unavailable charging facility is, for example, a charging facility that is not open during the time when the user travels in the charging required area 200 with the electric vehicle.

As described above, the area estimation unit 130 determines the positions of available charging facilities among the plurality of charging facilities installed in the charging required area 200. The output unit 140 causes the information terminal 30 to output position information of charging facilities that can be used in the charging required area 200 by superimposing the position information on the charging required area 200. In the example shown in FIG. 9, three icons CS corresponding to three available charging facilities are displayed at the positions of the respective charging facilities in the charging required area 200.

Further, detailed information DF of the three available charging facilities is displayed on the information terminal 30. The detailed information DF of the charging facilities includes a facility name, address, business hours, fixed holidays, the number of parking lots, and the number of pieces of fast charging equipment, in each of the charging facilities.

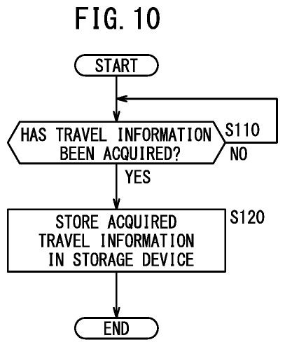

FIG. 10 is a flowchart illustrating a processing procedure relating to acquisition of the travel information 150 by the simulation device 10. This processing procedure is performed, for example, by the processing circuit 60 of the simulation device 10 executing a program stored in the storage device 70. When this processing procedure is started, in step S110, the travel information acquisition unit 100 determines whether or not the travel information 150 has been acquired from the internal combustion engine vehicle 40. If YES in step S110, the processing procedure proceeds to step S120. If NO in step S110, the processing procedure returns to step S110.

In step S120, the travel information acquisition unit 100 stores the acquired travel information 150 in the storage device 70. When the processing of step S120 is completed, this processing procedure is terminated.

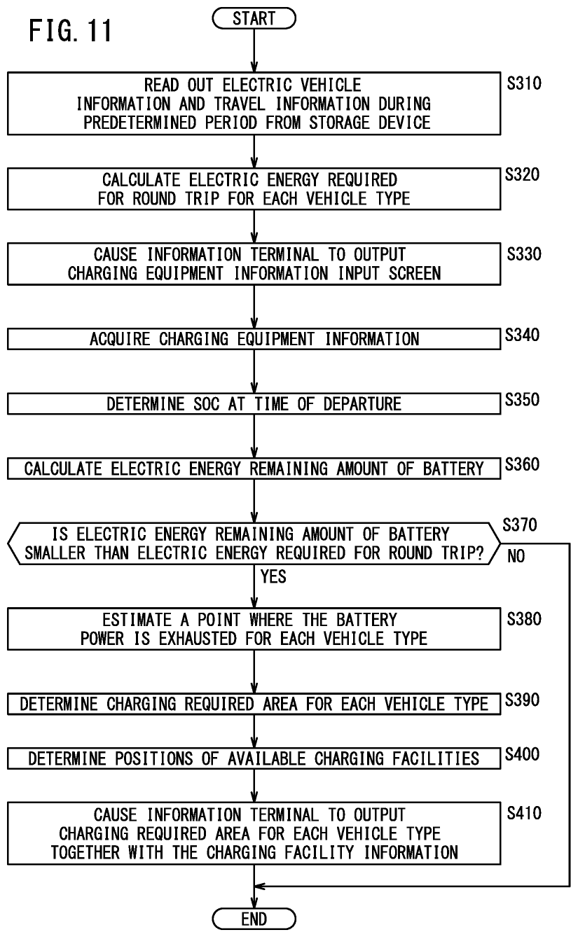

FIG. 11 is a flowchart illustrating a processing procedure relating to estimation of the charging required area 200 by the simulation device 10. This processing procedure is performed, for example, by the processing circuit 60 of the simulation device 10 executing a program stored in the storage device 70. When this processing procedure is started, in step S310, the electric energy calculating unit 120 reads out the electric vehicle information 170 and the travel information 150 acquired during the predetermined period the storage device 70.

In step S320, the electric energy calculating unit 120 calculates electric energy necessary for a round trip between the parking lot of the home OP and the work place DP for each of the vehicle types of electric vehicles. In step S330, the output unit 140 causes the information terminal 30 of the user to output a charging equipment information input screen relating to whether or not the charging equipment is installed in the parking lot of the home OP. In step S340, the charging equipment information acquisition unit 110 acquires the charging equipment information from the information terminal 30.

In step S350, the area estimation unit 130 determines the SOC of the battery of the electric vehicle at the time when the user leaves the home OP, based on the charging equipment information. In step S360, the area estimation unit 130 calculates the electric energy remaining amount of the battery for each of vehicle types of electric vehicles, based on the determined SOC and the battery capacity included in the electric vehicle information 170. When the charging equipment is installed in the parking lot of the home OP, the electric vehicle is fully charged.

In step S370, the area estimation unit 130 compares the electric energy remaining amount of the battery with the electric energy required for a round trip between the parking lot of the home OP and the work place DP. If the electric energy remaining amount of the battery is smaller than the electric energy required for the round trip, the processing procedure proceeds to step S380. When the electric energy remaining amount of the battery is equal to or larger than the electric energy required for the round trip, the present processing procedure is terminated.

In step S380, the area estimation unit 130 estimates a point where the battery power is exhausted for each vehicle type. In step S390, the area estimation unit 130 determines the charging required area 200 for each vehicle type. In step S400, the area estimation unit 130 determines the positions of charging facilities available within the charging required area 200. In step S410, the output unit 140 causes the information terminal 30 to output the charging required area 200 for each vehicle type together with the charging facility information. The charging facility information includes the icons CS indicating the positions of charging facilities available in the charging required area 200 and detailed information DF of the charging facilities. When the processing of step S410 is completed, this processing procedure is terminated.

[Invention Obtained from Embodiment]

A description will be given below concerning invention that can be grasped from the above-described embodiment.

(1) The simulation device (10) includes the travel information acquisition unit (100) configured to acquire travel information (150) from the internal combustion engine vehicle (40) equipped with an internal combustion engine, the travel information including the travel history of the internal combustion engine vehicle, the electric vehicle information storage unit (74) configured to store the electric vehicle information (170) about traveling performance of the electric vehicle, the map information storage unit (76) configured to store the map information (190) including the road information, the electric energy calculating unit (120) configured to calculate electric energy required in the case where the electric vehicle is used for the round trip between the storage location (OP) of the internal combustion engine vehicle and the destination (DP) based on the travel information, based on the electric vehicle information and the travel information acquired during the predetermined period, the area estimation unit (130) configured to estimate the charging required area (200) in which the electric vehicle needs to be charged during the round trip, based on the calculated electric energy, the electric vehicle information, and the map information, and the output unit (140) configured to cause the information terminal (30) of a user of the internal combustion engine vehicle to output the charging required area. Thus, the image when the electric vehicle is used can be evoked in the user. As a result, it is possible to promote vehicle replacement by the user.

(2) The electric vehicle may include the plurality of electric vehicles. The electric vehicle information storage unit may store the electric vehicle information for each of the vehicle types (E1, E2, E3) of the electric vehicles, the area estimation unit may estimate the charging required area for each of the vehicle types, and the output unit may cause the information terminal to output the charging required area for each of the vehicle types. Thus, the user can consider purchasing an electric vehicle by comparing the charging required areas for each type of vehicle.

(3) The simulation device may further include the charging equipment information acquisition unit (110) configured to acquire the charging equipment information about whether or not the charging equipment is installed in the storage location, wherein in the case where the charging equipment is installed in the storage location, the area estimation unit may estimate the charging required area assuming that the electric vehicle is in a fully charged state at the time of departure from the storage location. Thus, the user can consider the necessity of purchasing a home charging equipment together with an electric vehicle.

(4) The map information may include, together with the road information, the charging facility information including the position of the charging facility in which the electric vehicle is charged during the round trip, and the area estimation unit may estimate the charging required area and determine the position of the charging facility available in the charging required area based on the map information and the travel information acquired during the predetermined period, and the output unit may cause the information terminal to superimpose and output the position of the charging facility available in the charging required area, on the charging required area. Thus, the user can consider purchasing an electric vehicle in view of convenience of a charging facility.

The present invention is not limited to the above disclosure, and various modifications are possible without departing from the essence and gist of the present invention.

1. A simulation device comprising:
an electric vehicle information storage unit configured to store electric vehicle information about traveling performance of an electric vehicle;
a map information storage unit configured to store map information including road information; and
one or more processors that execute computer-executable instructions stored in a memory,
wherein the one or more processors execute the computer-executable instructions to cause the simulation device to:
perform travel information acquisition to acquire travel information from an internal combustion engine vehicle equipped with an internal combustion engine, the travel information including a travel history of the internal combustion engine vehicle;
perform electric energy calculation to calculate electric energy required in a case where the electric vehicle is used for a round trip between a storage location of the internal combustion engine vehicle and a destination based on the travel information, based on the electric vehicle information and the travel information acquired during a predetermined period;
perform area estimation to estimate a charging required area in which the electric vehicle needs to be charged during the round trip, based on the calculated electric energy, the electric vehicle information, and the map information; and
cause an information terminal of a user of the internal combustion engine vehicle to output the charging required area.

2. The simulation device according to claim 1, wherein the electric vehicle comprises a plurality of electric vehicles, the electric vehicle information storage unit stores the electric vehicle information for each of vehicle types of the electric vehicles, and
the one or more processors are configured to:
estimate the charging required area for each of the vehicle types in the area estimation; and
cause the information terminal to output the charging required area for each of the vehicle types.

3. The simulation device according to claim 1, wherein the one or more processors are configured to:
acquire charging equipment information about whether or not charging equipment is installed in the storage location; and
in a case where the charging equipment is installed in the storage location, the charging required area is estimated in the area estimation assuming that the electric vehicle is in a fully charged state at time of departure from the storage location.

4. The simulation device according to claim 2, wherein the one or more processors are configured to:
acquire charging equipment information about whether or not charging equipment is installed in the storage location; and
in a case where the charging equipment is installed in the storage location, the charging required area is estimated in the area estimation assuming that each of the electric vehicles is in a fully charged state at time of departure from the storage location.

5. The simulation device according to claim 1, wherein the map information includes, together with the road information, charging facility information including a position of a charging facility in which the electric vehicle is charged during the round trip, and
the one or more processors are configured to:
estimate the charging required area in the area estimation and determine the position of the charging facility available in the charging required area based on the map information and the travel information acquired during the predetermined period; and
cause the information terminal to superimpose and output the position of the charging facility available in the charging required area, on the charging required area.

6. The simulation device according to claim 2, wherein the map information includes, together with the road information, charging facility information including a position of a charging facility in which each of the electric vehicles is charged during the round trip, and
the one or more processors are configured to:
estimate the charging required area in the area estimation and determine the position of the charging facility available in the charging required area based on the map information and the travel information acquired during the predetermined period; and
cause the information terminal to superimpose and output the position of the charging facility available in the charging required area, on the charging required area.

7. The simulation device according to claim 3, wherein the map information includes, together with the road information, charging facility information including a position of a charging facility in which the electric vehicle is charged during the round trip, and
the one or more processors are configured to:
estimate the charging required area in the area estimation and determine the position of the charging facility available in the charging required area based on the map information and the travel information acquired during the predetermined period; and
cause the information terminal to superimpose and output the position of the charging facility available in the charging required area, on the charging required area.

8. The simulation device according to claim 4, wherein the map information includes, together with the road information, charging facility information including a position of a charging facility in which each of the electric vehicles is charged during the round trip, and
the one or more processors are configured to:
estimate the charging required area in the area estimation and determine the position of the charging facility available in the charging required area based on the map information and the travel information acquired during the predetermined period; and
cause the information terminal to superimpose and output the position of the charging facility available in the charging required area, on the charging required area.
